(19) United States
(12) Patent Application Publication
(10) Pub. No.: US 2003/0067020 A1
(43) Pub. Date: Apr. 10, 2003

(54) Semiconductor device

(76) Inventor: Masanori Itoh, Tokyo (JP)

Correspondence Address: RABIN & CHAMPAGNE, PC, 1101 14TH STREET, NW, SUITE 500, WASHINGTON, DC, 20005, US

(21) Appl. No.: 10/263,680

(22) Filed: Oct. 4, 2002

(30) Foreign Application Priority Data
Oct. 10, 2001 (JP) 2001-312282

(51) Int. Cl. H01L 29/80

(52) U.S. Cl. 257/276

(57) ABSTRACT

A semiconductor device (10) includes a first electrically conductive portion (14, 16) formed on a semiconductor substrate (11), a second electrically conductive portion (20) formed so as to intersect the first electrically conductive portion, a bridge portion (23) formed at an intersecting portion of the second electrically conductive portion with the first electrically conductive portion to define a gap (22) between the second electrically conductive portion and the first electrically conductive portion by the intersecting portion, protruding portions (24) which are formed at non-intersecting portions of at least one of the first electrically conductive portion and the second electrically conductive portion, and define spaces (25) therebelow, and a protective film (26) formed on the semiconductor substrate so as to cover both electrically conductive portions and having a surface shape associated with the bridge portion and the protruding portions.

### BACKGROUND OF THE INVENTION

1. Field of the Invention

The present invention relates to a semiconductor device excellent in high-frequency characteristic, like a field effect transistor formed on a GaAs substrate, for example, and particularly to a semiconductor device provided with an air bridge for achieving an improvement in high-frequency characteristic.

2. Description of the Related Art

A multilayered wiring structure is known as a wiring technique for a semiconductor device. According to it, an interlayer insulating film is interposed between a lower wiring and an upper wiring formed thereabove, thereby making it possible to form them so as to intersect each other. Meanwhile in a semiconductor device dealing with a high frequency, parasitic capacitance at an intersecting portion of both wirings exerts a great influence on the electrical characteristic of the semiconductor device.

Thus in order to achieve a reduction in the parasitic capacitance, the formation of a bridge portion for defining a gap or space between a second electrically conductive portion corresponding to an upper wiring and a first electrically conductive portion corresponding to a lower wiring, at an intersecting portion of the second electrically conductive portion with the first electrically conductive portion, has been implemented with the object of reducing parasitic capacitance between the first electrically conductive portion and the second electrically conductive portion intersecting the first electrically conductive portion.

This structure is generally called an air bridge wiring structure. The gap exhibits a dielectric constant higher than that of an insulative protective film formed so as to cover both the conductive portions. Thus according to the air bridge wiring structure, the electrical characteristic of the semiconductor device can be improved owing to the reduction in the parasitic capacitance between both electrically conductive portions.

Since, however, the bridge portion protrudes upward under the protective layer, a protrusion corresponding to the bridge portion is formed at a place or spot corresponding to the bridge portion, of the protection layer.

There is a fear that when an external pressing force concentratedly acts on the protrusion on the protective layer, the bridge portion will deform and hence the gap between both electrically conductive portions could be reduced, thereby increasing the parasitic capacitance. There is also a fear of the bridge portion developing a short circuit in the lower conductive portion therebelow under the pressing force.

### SUMMARY OF THE INVENTION

The present invention may provide a semiconductor device having an air bridge wiring structure free of concentrated action of an external pressing force.

In order to achieve the above object, the present invention adopts the following configuration.

A semiconductor device according to the present invention comprises a first electrically conductive portion formed on a semiconductor substrate, a second electrically conductive portion formed on the first electrically conductive portion so as to intersect the same, a bridge portion formed at an intersecting portion of the second electrically conductive portion with the first electrically conductive portion to define a gap between the second electrically conductive portion and the first electrically conductive portion by the intersecting portion, protruding portions respectively formed at mutually non-intersecting portions of at least one of the first electrically conductive portion and the second electrically conductive portion, the protruding portions defining spaces therebelow, and a protective film formed on the semiconductor substrate so as to cover both the electrically conductive portions and having a surface shape associated with the bridge portion and the protruding portions.

According to the semiconductor device according to the present invention, owing to the existence of the protruding portions formed in a region other than the bridge portion at both the electrically conductive portions disposed so as to intersect each other, protruding portions associated with the protruding portions are formed on the protective film for covering both the electrically conductive portions. Thus when a pressing force acts on the upper surface of the protective film through a flat surface, for example, while the semiconductor device is being handled, the pressing force is dispersed over the protruding portion associated with the bridge portion of the protective film and the protruding portions associated with the protruding portions other than the bridge portion, and hence the pressing force can be prevented from concentratedly acting on the bridge portion. Thus the bridge portion can be increased relatively in mechanical strength.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a cross-sectional view partly showing a preferred embodiment 1 of a semiconductor device according to the present invention;

FIG. 2 is a perspective view partly illustrating a preferred embodiment 2 of the semiconductor device according to the present invention;

FIG. 3 is a plan view schematically showing a preferred embodiment 3 of the semiconductor device according to the present invention;

FIG. 4 is a cross-sectional view partly depicting a preferred embodiment 4 of the semiconductor device according to the present invention;

FIG. 5 is a plan view schematically showing a preferred embodiment 5 of the semiconductor device according to the present invention; and

FIG. 6 is a cross-sectional view obtained along line VI-VI shown in FIG. 5.

### DETAILED DESCRIPTION OF THE PREFERRED EMBODIMENTS

The present invention will hereinafter be described in detail with reference to illustrated embodiments.

<Embodiment 1>

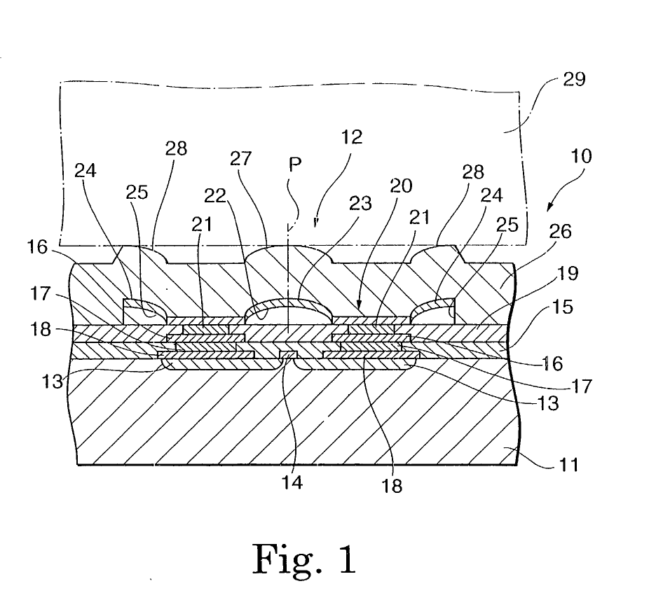

FIG. 1 partly shows a preferred embodiment 1 of a semiconductor device according to the present invention.

In the embodiment illustrated in FIG. 1, the semiconductor device 10 according to the present invention is provided with a semiconductor substrate 11 comprising, for example, a GaAs semiconductor substrate, in which carrier mobility exhibits a high value suitable for a high frequency. A conventionally well-known field effect transistor 12 is built in the semiconductor substrate 11.

As conventionally well known, the transistor 12 has a source/drain which comprises a pair of impurity regions 13 and 13 formed on the semiconductor substrate 11 with an interval defined therebetween. A gate 14 is disposed within a region between the source/drain (13 and 13) on the semiconductor substrate 11 with a conventionally well-known gate oxide film (not shown) interposed therebetween. The gate 14 extends forward and backward with respect to the sheet of FIG. 1 at right angles to the sheet of FIG. 1.

A first insulating film 15, which buries the gate 14, is formed on the semiconductor substrate 11. Lower wirings 16 and 16 formed in a first metal layer, are formed on the first insulating film 15. The lower wirings 16 extend forward and backward with respect to the sheet at right angles to the sheet of FIG. 1 in a manner similar to the gate 14.

In the embodiment shown in FIG. 1, both lower wirings 16 and 16 are connected to their corresponding impurity regions 13 and 13 through contact portions 17 and 17 extending within the insulating film 15, and ohmic electrodes 18 and 18 for obtaining ohmic contact between the contact portions and the impurity regions 13 and 13 for the source/drain.

A drain voltage is applied to the source/drain (13 and 13) comprising the impurity regions through both the lower wirings 16 and 16. When a gate voltage exceeding a threshold value is applied to the gate 14 in a state in which the drain voltage is being applied thereto, a channel current flows between the source/drain (13 and 13) as conventionally well known. Thus the channel current that flows between the source/drain (13 and 13), can be intermittently controlled under the control of the gate voltage.

A second insulating film 19 is formed on the first insulating film 15 to embed the first metal layer (16 and 16) including the lower wirings formed on the first insulating film 15.

An upper wiring 20 formed of a second metal layer is formed on a second insulating film 19. The upper wiring 20 extends over the second insulating film 19 in a direction orthogonal to the direction in which the gate 14 corresponding to a first electrically conductive portion extends. Thus the upper wiring 20 is formed over the gate 14 so as to intersect the gate 14.

The upper wiring 20 is connected to a desired electrically conductive portion such as either one of the lower wirings 16 and 16, other lower wiring portion of the first metal layer except for these lower wirings 16 and 16, or other electrically conductive portion on the semiconductor substrate 11 through contact portions 21 extending within the second insulating film 19 as needed.

While both the insulating films 15 and 19 are interposed between the gate 14 corresponding to the first electrically conductive portion and the upper wiring 20 corresponding to a second electrically conductive portion disposed on the gate, both the electrically conductive portions 14 and 20 are disposed so as to intersect each other. An air bridge portion 23 for defining a gap or space 22 below a portion where the upper wiring 20 intersects the gate 14, is formed at a portion thereof crossing the gate 14, i.e., the intersecting portion.

The air bridge portion 23 comprises an upwardraided protruding portion or protrusion. In the illustrated embodiment, the air bridge portion 23 has a convex sectional shape extending along an arch-shaped curved surface. Since the air bridge portion 23 defines the gap 22 exhibiting a dielectric constant higher than those of the insulating films 15 and 19 or that of a protective film to be described later between the mutually-intersecting portions of both the electrically conductive portions 14 and 20, the air bridge portion 23 prevents the occurrence of substantial parasitic capacitance developed between both the electrically conductive portions 14 and 20 as conventionally well known, or achieves a reduction in parasitic capacitance.

In the semiconductor device 10 according to the present invention, protruding portions 24 are formed at the upper wiring 20 provided with the air bridge portion 23.

In the illustrated embodiment, the pair of protruding portions 24 are arranged-in line in the longitudinal or extending direction of the upper wiring 20 with the air bridge portion 23 interposed therebetween in such a manner that they are spaced away from each other in the neighborhood of the air bridge portion 23.

In the illustrated embodiment, the pair of protruding portions 24 are raised upwardly to the outside along an arc curved line of the air bridge portion 23 from the neighborhood of both ends of the air bridge portion 23 so as to coincide with shapes of one half thereof and the other half thereof with a virtual surface P crossing the center of the air bridge portion 23 as the boundary as viewed in a cross-section of the air bridge portion 23. Namely, the protruding portions 24 respectively have sectional shapes divided into the left and right halves as viewed in the sectional shape of the air bridge portion 23. Both the protruding portions 24 are disposed symmetrically with each other with the air bridge portion 23 interposed therebetween.

Each of the protruding portions 24 has a vertical size substantially equal to the vertical size of the air bridge portion 23. The respective protruding portions 24 respectively define gaps 25 between the same portions and the upper surface of the second insulating film 19 placed therebelow.

The sectional shapes of the protruding portions 24 can be formed as arc curved surfaces each of which coincides with the sectional shape of the air bridge portion 23. However, the shape of each protruding portion 24 may preferably be set to half the shape of the air bridge portion 23 as shown in the drawing to reduce the area occupied by the protruding portion 24.

As long as the gap is defined between each of the protruding portions 24 and the insulating film 19 therebelow, the protruding portions 24 are not limited to the shape extending along the sectional shape of the air bridge portion 23. Various sectional shapes implementable by a combination of straight lines of a triangle or the like or a combination of a curved line and a straight line can be provided for the protruding portions 24.

Either one of the pair of protruding portions 24 can be made unnecessary or a larger number of the similar protruding portions can be formed at the upper wiring 20.

As an alternative to the coincidence of the vertical size of each protruding portion 24 with that of the air bridge portion 23, the vertical size thereof can be set smaller or larger than that of the air bridge portion.

The respective protruding portions 24 are formed in the process of forming the upper wiring 20 having the air bridge portion 23, which is similar to the prior art.

While the second metal layer is deposited on the second insulating film 19 to form the upper wiring 20, resists extending along the shapes of the gaps 22 and 25 on the second insulating film 19 are formed at places to form the gaps 22 and 25 on the second insulating film 19 in advance of the deposition of the second metal layer. As conventionally well known, a photoresist material is applied onto the second insulating film 19 with a predetermined thickness and thereafter subjected to selective exposure and development, whereby the resists can be formed.

After the resists have been formed in association with the gaps 22 and 25 on the second insulating film 19, the second metal layer is deposited on the second insulating film 19 so as to cover the resists. The second metal layer is subjected to photolithography and etching processing to thereby remove unnecessary portions except for the upper wiring 20 and other upper wirings of the second metal layer.

Thereafter the resists extending along the shapes of the gaps 22 and 25 are removed to thereby form the air bridge portion 23 and the upper layer 20 having the respective protruding portions 24.

After the formation of the upper wirings including the upper wiring 20, a protective film 26 formed of an insulating material like, for example, a silicon nitride film is deposited on the second insulating film 19 by, for example, a plasma CVD method to cover components containing the upper wirings on the second insulating film 19.

Owing to the deposition of the protective film 26 as conventionally well known, the gap 22 placed below the air bridge portion 23 is ensured without such a deposited material being introduced around into below the air bridge portion 23. Tn a manner similar to it, the gaps 25 are ensured even below the respective protruding portions 24 without the portions below the respective portions 24 being buried by the deposited material.

Since the surface of the protective film 26 takes a shape along the surface form of the second insulating film 19 with the protective film deposited thereon, a protruding portion 27 having a shape corresponding to the air bridge portion is formed on the surface of the protective film 26 at a position corresponding to the air bridge portion 23, and protruding portions 28 each having a shape corresponding to the protruding portion are respectively formed at positions corresponding to the respective protruding portions 24.

Since the air bridge portion 23 and the respective protruding portions 24 respectively have vertical sizes substantially equal to each other in the embodiment shown in FIG. 1, the respective protruding portions 27 and 28 are substantially equal in vertical size and raised upward from a flat surface portion of the surface of the protective film 26.

In the semiconductor device 10 according to the present invention, when the surface of the protective film 26 is placed under a pressing force applied from an object 29 having a flat surface, for example, the pressing force is dispersed over the protruding portion 27 and the protruding portions 28. Therefore the pressing force does not concentratedly act on the protruding portion 27 and hence the mechanical strength of the air bridge portion 23 placed below the protruding portion 27 is relatively increased.

It is thus possible to protect deformation or damage of the air bridge portion 23 due to an external force and prevent degradation of the electrical characteristic of the semiconductor device 10 due to the deformation or damage.

As is apparent from the above description, the vertical size of each protruding portion 24 provided at the upper wiring 20 is set higher than that of the air bridge portion 23, so that the vertical sizes of the protruding portions 28 corresponding to the respective protruding portions 24 can be set higher than the vertical size of the protruding portion 27 associated with the air bridge portion 23. Therefore the protruding portions 28 can receive an external force prior to the action of the external force on the protruding portions, whereby the air bridge portion 23 can be protected more reliably.

Even if the vertical sizes of the respective protruding portions 24 provided at the upper wiring 20 are set smaller than the vertical size of the air bridge portion 23, the protruding portion 27 corresponding to the air bridge portion 23 will deform. Thus when the protruding portion 27 and the protruding portions 28 of the respective protruding portions 24 become equal to one another in vertical size due to such deformation, the external force is dispersed and hence the damage that would lead to destruction of the air bridge portion 23, can be reliably prevented.

<Preferred Embodiment 2>

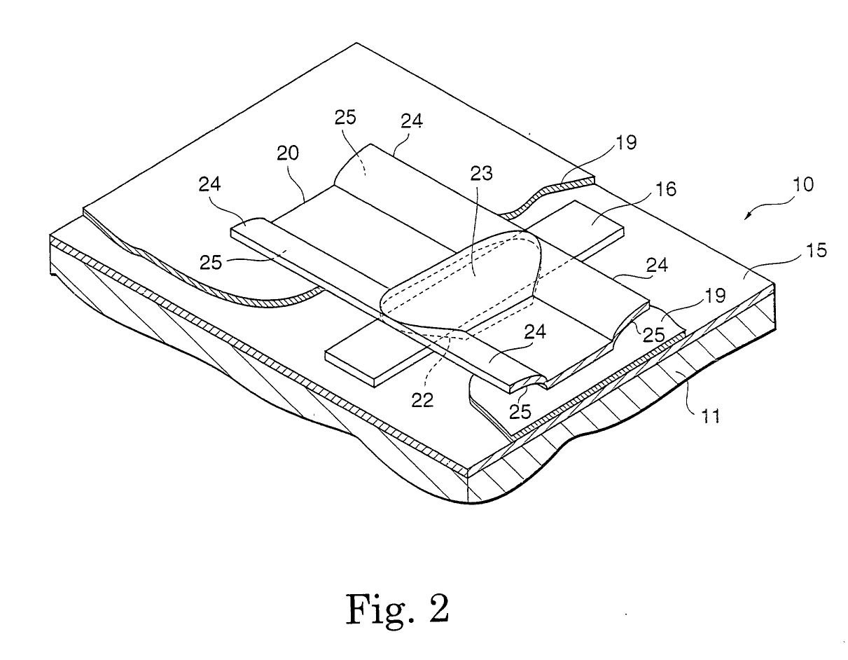

FIG. 2 shows an embodiment in which protruding portions each of which acts in a manner similar to the above, are formed in connection with a portion where a lower wiring 16 corresponding to a first electrically conductive portion formed on a first insulating film 15 disposed on the semiconductor substrate 11, and an upper wiring 20 corresponding to a second electrically conductive portion formed on a second insulating film 19 for covering the lower wiring 16 intersect each other.

An air bridge portion 23 similar to the above is formed at the intersecting portion of the upper wiring 20 placed so as to intersect the lower wiring 16. A gap or space 22 is defined between the air bridge portion 23 and the second insulating film 19 for covering the lower wiring 16 as viewed from below the air bridge portion 23.

Protruding portions 24 similar to ones shown in FIG. 1, which substantially coincide with an arc curved line of the air bridge portion 23, and which are raised outside in an upward direction and have vertical sizes each substantially equal to the vertical size of the air bridge portion 23 as viewed in a cross-section that crosses the longitudinal direction of the upper wiring, are formed at both edges of the upper wiring 20.

While omitted for simplification of the drawing in FIG. 2, a protective film 26 similar to one illustrated in the preferred embodiment 1 is formed on the second insulating film 19. The protective film (26) is formed with a protruding portion (27) corresponding to the air bridge portion 23 and protruding portions (28) corresponding to the respective protruding portions 24, both of which are similar to those illustrated in the preferred embodiment 1.

Thus even in a semiconductor device 10 shown in the preferred embodiment 2, the air bridge portion 23 can relatively be increased in mechanical strength and reliably protected from an external force in a manner similar to the preferred embodiment 1.

<Preferred Embodiment 3>

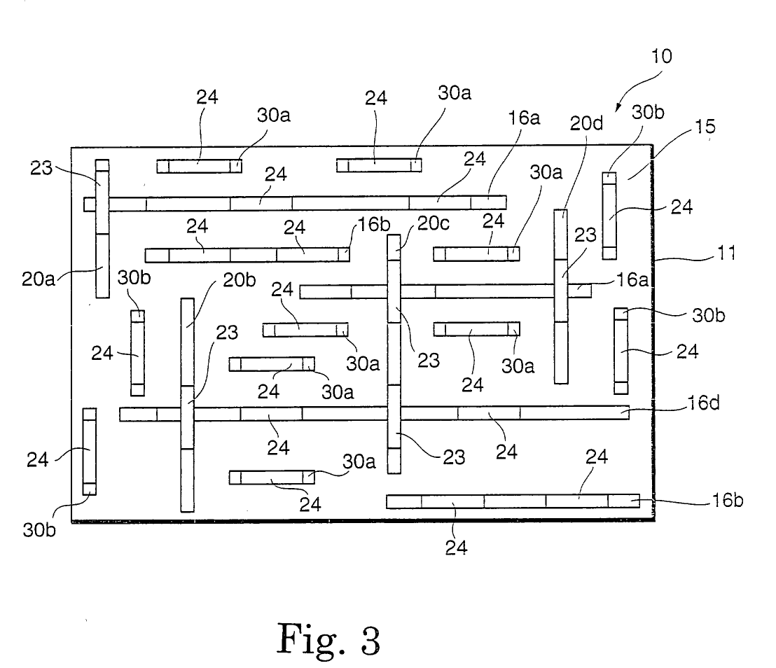

While the preferred embodiments 1 and 2 respectively show the case in which the protruding portions 24 are formed at the non-intersecting portions of the upper wiring 20 provided with the air bridge portion 23, protruding portions 24 that perform action similar to the above, can be formed at electrically-conductive portions or dummy wirings each free of the air bridge portion 23 as shown in FIG. 3 as an alternative to the embodiments.

In a semiconductor device 10 shown in a preferred embodiment 3, a large number of lower wirings 16 (16a through 16e) each formed of a first metal layer and extending in a horizontal direction, and a plurality of dummy wirings 30a, which respectively extend in parallel with the lower wirings 16 but do not function as wirings, are provided on a first insulating film 15 formed on the semiconductor substrate 11 as shown in FIG. 3.

Although omitted in FIG. 3 for simplification of the drawing, a second insulating film (19) similar to the above, which covers the lower wirings 16 formed of the first metal layer and the dummy wirings 30a, is formed. Further, a large number of upper wirings 20 (20a through 20d) each formed of a second metal layer and extending in a vertical direction, and a plurality of dummy wirings 30b, which respectively extend in parallel with the upper wirings 20 but do no function as wirings, are provided on the second insulting film.

The upper wiring 20a is disposed so as to intersect the lower wiring 16a, the upper wiring 20b is disposed so as to intersect the lower wiring 16d, the upper wiring 20c is placed so as to intersect the lower wirings 16c and 16d, and the upper wiring 20d is placed so as to intersect the lower wiring 16c.

Arc-shaped air bridge portions 23 for defining gaps or spaces (22) similar to the above are formed at the intersecting portions of the respective upper wirings 20 (20a through 20d).

Although not illustrated in the drawing, the dummy wirings 30 (30a and 30b) are suitably disposed between the respective wirings 20 as conventionally well known to bring wiring density on the semiconductor substrate 11 into uniformity with a view toward achieving the flattening of a protective film (26) similar to the above.

In the preferred embodiment 3, the lower wirings 16a and 16d free of the air bridge portions 23, of the mutually-intersecting lower wirings 16 (16a, 16c and 16d) and upper wirings 20 (20a through 20d) are respectively formed with dummy air bridge portions 24 corresponding to protruding portions each having a shape substantially coincident with that of the air bridge portion 23.

In the embodiment shown in FIG. 3, the non-intersecting lower wirings 16b are formed with a plurality of dummy air bridge portions 24 similar to the above in their extending directions with spaces mutually left therebetween.

Further dummy air bridge portions 24 are formed on the dummy wirings 30 (30a and 30b) respectively.

In order to cover these lower wirings 16, upper wirings 20 (20a through 20d) and dummy wirings 30 (30a and 30b), the protective film (26) is formed on the second insulating film (19). Although not shown in the drawing, protruding portions each having a shape similar to that of the protruding portion 27 shown in FIG. 1 are formed on the protective film so as to correspond to the air bridge portions 23 and the dummy air bridge portions 24.

While there is a difference equivalent to the thickness dimension of the second insulating film (19) between each of the dummy air bridge portions 24 formed on the lower wirings 16 and the dummy air bridge portions 24 formed on the lower dummy wirings 30a, and each of the dummy air bridge portions 24 formed on the upper dummy wirings 30b, the insulating film is extremely thin and hence the difference between the two does not exert a substantial influence on protective action of each air bridge portion 23.

Thus according to the semiconductor device 10 shown in the preferred embodiment 3, the air bridge portions 23 can be increased relatively in mechanical strength and reliably protected from an external force in a manner similar to the preferred embodiments 1 and 2.

Further according to the semiconductor device 10 shown in the preferred embodiment 3, the non-intersecting wirings or the dummy wirings or the like are used to thereby make it possible to form the dummy air bridge portions 24 on the non-intersecting wirings or the dummy wirings or the like. Therefore a large number of the dummy air bridge portions 24 can effectively be disposed in dispersed form without interfering with making the semiconductor device 10 compact, whereby the air bridge portions 23 can effectively be protected.

While the respective protruding portions are formed by the dummy air bridge portions 24 having the shapes similar to those of the air bridge portions 23 in the embodiment shown in FIG. 3, protruding portions having shapes similar to those of the protruding portions 24 shown in FIG. 1 or desired shapes other than those can be adopted for the dummy air bridge portions 24 shown in the preferred embodiment 3 as an alternative to the above.

The following preferred embodiment shows an example in which the protective film (26) is contrived.

<Preferred Embodiment 4>

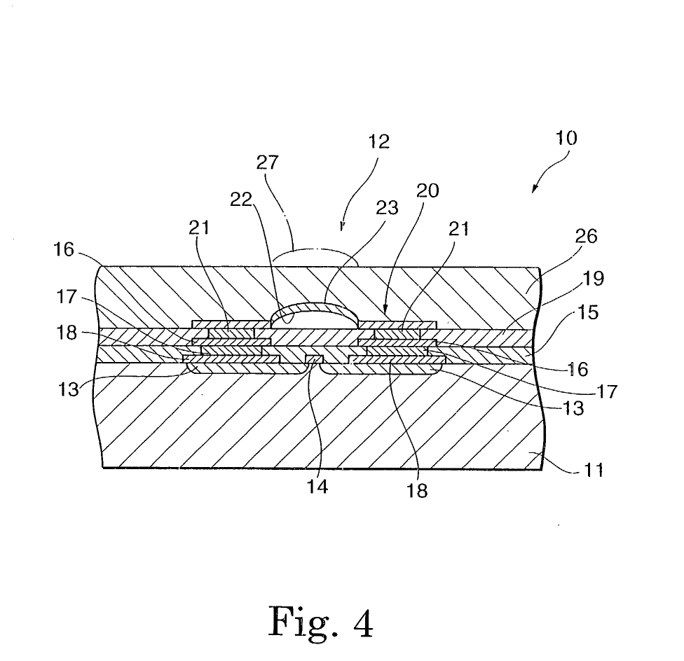

FIG. 4 showing a preferred embodiment 4 is a cross-sectional view of a semiconductor device 10. In FIG. 4, components, which carry out functions similar to the preferred embodiment 1 shown in FIG. 1, are respectively identified by the same reference numerals as those shown in FIG. 1.

While a structure including the transistor 12, which is under a protective film 26, is identical to a conventional one except for the provision of the protruding portions 24, a protruding portion 27 formed on the surface of the protective film 26 in association with an air bridge portion 23 of an upper wiring 20 has been removed by, for example, chemical mechanical polishing as indicated by a virtual line in FIG. 4 in the embodiment illustrated in FIG. 4.

Owing to the removal of the protruding portion 27, the surface of the protective film 26 is finished to a flat surface coincident with a predetermined flat level inclusive of a portion corresponding to a location where the air bridge portion 23 is provided.

Thus the removal of the protruding portion 27 allows prevention of the concentrated action of an external force on the air bridge portion 23 located below the protruding portion through the protruding portion.

<Preferred Embodiment 5>

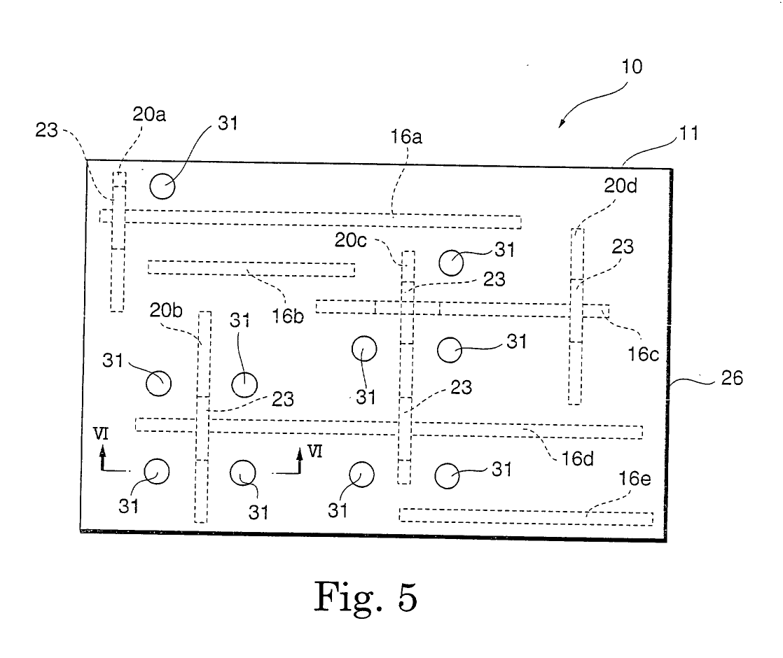

In a preferred embodiment 5 shown in FIG. 5, functional parts similar to those in the preferred embodiment 3 shown in FIG. 3 are respectively identified by the same reference numerals as those in the preferred embodiment 3. The first insulating film (15) and the second insulating film (19) are omitted in FIG. 5 for simplification of the drawing.

In a semiconductor device 10 shown in the preferred embodiment 5, protruding portions 31 are formed in the neighborhood of locations where air bridge portions 23 on the surface of a protective film 26 are provided, as an alternative to the formation of protruding portions (24) other than air bridge portions 23 at electrically conductive portions of lower wirings 16 (16a through 16e) or upper wirings 20 (20a through 20d) placed below the protective film 26.

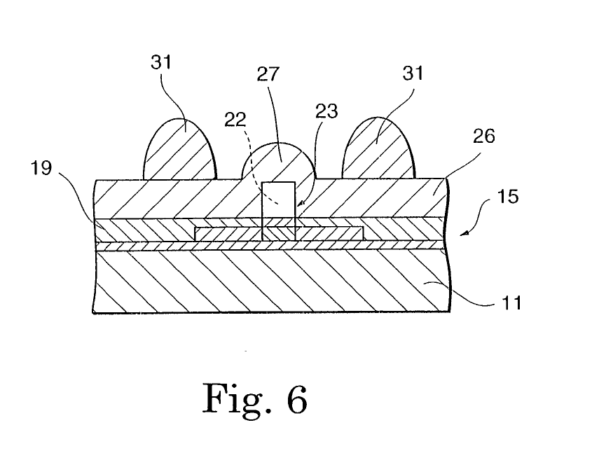

As is apparent from a cross-sectional view of FIG. 6, which is taken along line VI-VI shown in FIG. 5, each of the protruding portions 31 has a vertical size larger than that of a protruding portion 27 of the protective film 26, which is formed in association with an air bridge portion 23.

Thus the respective protruding portions 31 disperses a pressing force acting on the surface of the protective film 26 together with the respective protruding portions 27 formed in association with the air bridge portions 23 in a manner similar to the above-described embodiment to thereby protect the air bridge portion 23 disposed below the protruding portions 27.

Since the protruding portions 31 can basically be formed in desired positions on the surface of the protective film 26 regardless of the placement of the electrically conductive portions below the protective film 26, the protruding portions 31 can more efficiently be formed in their corresponding positions suitable for the protection of the air bridge portions 23.

The vertical sizes of the protruding portions 31 can be formed in vertical sizes lower than those of the protruding portions 27 in a manner similar to the protruding portions 28 respectively formed in association with the protruding portions 24 provided at the electrically conductive portions.

While the embodiments in which the present invention is applied to the semiconductor devices suitable for the high frequency, have been described above, the present invention is not limited to the embodiments. The present invention can be applied to a semiconductor device having various air bridge wiring structures.

As an alternative to the GaAs semiconductor substrate, a semiconductor substrate like an Si semiconductor substrate can suitably be used as the semiconductor substrate.

In the semiconductor device according to the present invention, as described above, the protruding portions associated with the protruding portions corresponding to the bridge portions are formed on the protective film for covering both the electrically conductive portions placed so as to intersect each other in addition to the protruding portions associated with the bridge portions owing to the existence of the protruding portions formed in the region other than the bridge portions at both the electrically conductive portions.

Since the pressing force, which acts on the upper surface of the protective film, is dispersed over the protruding portions associated with the bridge portions of the protective film and the protruding portions associated with the protruding portions other than the bridge portions, the pressing force can be prevented from concentratedly acting on the bridge portions.

Thus according to the present invention, the bridge portions can be increased relatively in mechanical strength. It is therefore possible to protect the air bridge structure from the external pressing force and prevent degradation of electrical characteristics due to deformation or damage of the air bridge structure.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

What is claimed is:

1. A semiconductor device, comprising:
a first electrically conductive portion formed on a semiconductor substrate;
a second electrically conductive portion formed on said first electrically conductive portion so as to intersect the same;
a bridge portion formed at an intersecting portion of said second electrically conductive portion with said first electrically conductive portion to define a gap between said second electrically conductive portion and said first electrically conductive portion by the intersecting portion;
protruding portions formed at mutually non-intersecting portions of at least one of said first electrically conductive portion and said second electrically conductive portion, said protruding portions defining spaces therebelow; and
a protective film formed on the semiconductor substrate so as to cover said both electrically conductive portions and having a surface shape associated with said bridge portion and said protruding portions.

2. The semiconductor device according to claim 1, wherein said protruding portions are formed at said second electrically conductive portion in line with said bridge portion in a longitudinal direction of said second electrically conductive portion.

3. The semiconductor device according to claim 1, wherein said protruding portions are formed in the neighborhood of said bridge portion with an interval left therebetween with respect to said bridge portion.

4. The semiconductor device according to claim 2, wherein said protruding portions are formed as paired with each other on both end sides of said bridge portion with said bridge portion being interposed therebetween.

5. The semiconductor device according to claim 1, wherein said protruding portions are dummy bridge portions each having a shape substantially coincident with at least part of said bridge portion.

6. The semiconductor device according to claim 4, wherein said both protruding portions formed as paired have shapes substantially coincident with respective shapes of one half and the other half of a virtual surface that crosses the center of said bridge portion formed between said both protruding portions.

7. The semiconductor device according to claim 1, further including,
a third electrically conductive portion which is formed on the semiconductor substrate and unintersects said first and second electrically conductive portions, and
protruding portions formed on said third electrically conductive portion, for defining gaps below said protruding portions.

8. The semiconductor device according to claim 1, further including,
dummy wirings which are formed on the semiconductor substrate and unfunction as wirings, and
protruding portions respectively formed on the dummy wirings, for defining gaps below said protruding portions.
